(19) United States
(12) Patent Application Publication
(10) Pub. No.: US 2024/0363670 A1
(43) Pub. Date: Oct. 31, 2024

(54) METHOD FOR STABLIZING LINE-OF-SIGHT FALLING POINT

(71) Applicant: Reco BioTek Co., Ltd, Toufen City (TW)

(72) Inventors: Chang Cheng Fan, Toufen City (TW); Chang Meng Chih, Toufen City (TW); Tsai Cheng Feng, Toufen City (TW)

(21) Appl. No.: 18/203,718

(22) Filed: May 31, 2023

(30) Foreign Application Priority Data
Apr. 27, 2023 (TW) 112115881

(51) Int. Cl. H01L 27/146

(52) U.S. Cl. CPC H01L 27/14683; H01L 27/14618

(57) ABSTRACT

Disclosed is a method for manufacturing an image sensor module. The method comprises the steps of: disposing a glass cover on a substrate; sawing the glass cover into a plurality of glass units; forming an individual solidified interface filler between the adjacent glass units; sawing along the centerline of each solidified interface filler to form a plurality of independent electronic semi-finished products for complementary metal oxide semiconductor image sensor (CMOS Image Sensor, CIS) packaging; and performing an image sensor molded ball grid array (ImBGA) process to obtain the image sensor module.

### CROSS-REFERENCE TO RELATED APPLICATIONS

This application claim priority to Taiwanese application Numbered 112115881, filed Apr. 27, 2023, which is herein incorporated by reference in its' integrity.

### BACKGROUND OF THE INVENTION

### Field of the Invention

The present disclosure relates to a method for manufacturing optical elements, in particular to a method for manufacturing an image sensor module.

### Description of the Related Art

Generally speaking, an image sensor is a device that converts optical signals into analog electrical signals. In particular, the image sensor outputs the analog electrical signal to an image signal processor for processing such as analog/digital conversion (A/D conversion) and color adjustment, and then becomes digital image information. In the prior art, the commonly used image sensor is, for example, a charge coupled device (CCD) or a complementary metal-oxide semiconductor (CMOS) image sensor. In addition, in the prior art, a so-called CIS is an abbreviation of complementary metal oxide semiconductor image sensor (CMOS Image Sensor). At present, the application of CIS is very extensive. For example, the CIS is constantly expanding in various fields such as automobile, safety as well as medical treatment and manufacturing thereof.

Conventionally, the method for manufacturing a CIS module is as follows. Firstly, an image sensor chip is disposed on an IC board. Subsequently, a wire bonding process is performed so that the bonding pads on the image sensor chip and the bonding pads on the IC substrate are bonded through gold wires. Then, a transparent glass cover is attached to the image sensor chip to protect the image sensor area. Thereafter, a protective layer is coated to protect the gold wire and the image sensor chip. Finally, solder balls are disposed on the lower surface of the IC substrate to form a CIS module structure. In the prior art, the upper and lower surfaces of the transparent glass cover are respectively coated with an anti-reflection coating material layer to reduce the reflection of the transparent glass cover and the loss when light passes through the transparent cover, thereby increasing the penetration rate. In doing so, the image quality of CIS products is improved.

For the sake of reduction in cost, a mold injection process is used with less adhesive material to protect the gold wire and the image sensor chip. However, the difference between the thermal expansion coefficients of the glue injection material and the glass cover material leads to that peeling easily takes place on the contact surface between the glass and the glue injection material under high and low temperature environments. In view of this, the prior art utilizes glue-coating process in which epoxy resin is applied on gold wire and glass as an intermediate buffer material prior to using a molding mold for one-time injection packaging, so as to reduce divestiture risk. However, such process still uses a large amount of gluing materials, thereby neither enhancing production efficiency nor effectively reducing material costs.

Therefore, providing a method for manufacturing an image sensor module that can solve the above-mentioned problems is an important issue in this technical field.

### SUMMARY OF THE INVENTION

In view of this, the purpose of the disclosed invention is to improve the line-of-sight point detection stability of the line-of-sight detection method. Disclosed is an exemplary a method for manufacturing an image sensor module, including: disposing a glass cover on a substrate; sawing the glass cover into a plurality of glass units; forming a plurality of solidified interface fillers, each being between the adjacent glass units; sawing along the centerline of each solidified interface filler to form a plurality of independent electronic semi-finished products for complementary metal oxide semiconductor image sensor (CMOS Image Sensor, CIS) packaging; and performing an image sensor molded ball grid array (ImBGA) process to obtain the image sensor module.

In another embodiment, each electronic semi-finished product forms an ImBGA module in the ImBGA process so that the image sensor module is obtained.

In another embodiment, each electronic semi-finished product is attached to a chip in the ImBGA process.

In another embodiment, after each electronic semi-finished product is attached to the chip, a sealing process is further performed by applying a sealant around a periphery region of each electronic semi-finished product to protect each electronic semi-finished product.

In another embodiment, the chip is located on an IC board, and various solder balls are further formed on an opposite surface of the IC board after the sealing process, thereby obtaining the ImBGA module.

In another embodiment, the solidified interface fillers serve as a buffer material between the electronic semi-finished products and the sealant.

In another embodiment, a first clean process is performed prior to the step of forming the solidified interface fillers between the adjacent glass units.

In another embodiment, a second clean process and a debonding process are further performed after the step of sawing along the centerline of each solidified interface filler.

Disclosed herein is another exemplary a method for manufacturing an image sensor module, including: disposing a glass cover on a substrate; sawing the glass cover into a plurality of glass units; performing a first clean process; forming an interfacial material between the adjacent glass units; solidifying the interfacial material to form various solidified interface fillers; sawing along the centerline of each solidified interface fillers; performing a second clean process; performing a debonding process to form a plurality of independent electronic semi-finished products for complementary metal oxide semiconductor image sensor (CMOS Image Sensor, CIS) packaging; and performing an image sensor molded ball grid array (ImBGA) process where each electronic semi-finished product forms an ImBGA module, thereby obtaining the image sensor module.

In another embodiment, each electronic semi-finished product is attached to the chip in the ImBGA process; thereafter, the chip is arranged on an IC board, and a sealing process is further performed by applying a sealant on a periphery region of each electronic semi-finished product to protect each electronic semi-finished product; and various solder balls are further formed on an opposite surface of the IC board subsequent to the sealing process, thereby obtaining the ImBGA module.

### BRIEF DESCRIPTION OF THE DRAWINGS

FIG. 1 is a flowchart showing a method for manufacturing an image sensor module in accordance with an embodiment of the present disclosure.

FIG. 2 to FIG. 5 illustrate specific steps of the method for manufacturing an image sensor module in accordance with an embodiment of the present disclosure.

FIG. 6 to FIG. 8 illustrate alternative glass covers for the image sensor module in accordance with embodiments of the present disclosure.

### DESCRIPTION OF THE PREFERRED EMBODIMENTS

First of all, it should be noted, compared to the foregoing conventional methods, that an exemplary method for manufacturing an image sensor module comprises the steps of: disposing a glass cover on a substrate; sawing the glass cover into a plurality of glass units; forming an individual solidified interface filler between the adjacent glass units; sawing along the centerline of each solidified interface filler to form a plurality of independent electronic semi-finished products for complementary metal oxide semiconductor image sensor (CMOS Image Sensor, CIS) packaging; and performing an image sensor molded ball grid array (ImBGA) process to obtain the image sensor module.

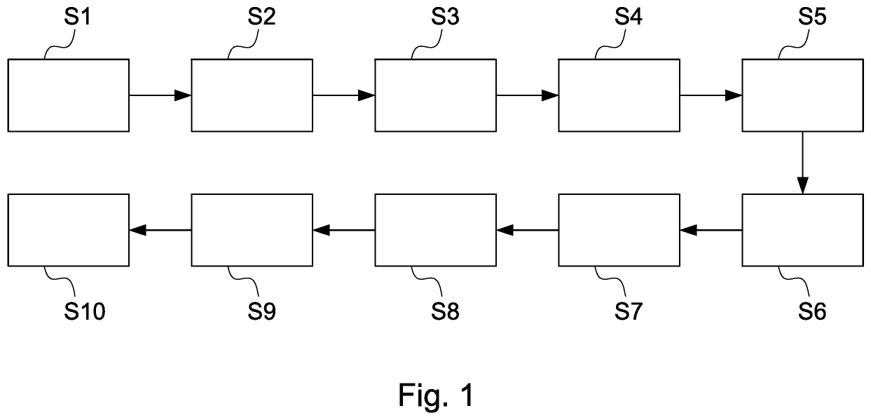

For more details, please refer to FIG. 1, which is a flowchart showing a method for manufacturing an image sensor module in accordance with an embodiment of the present disclosure. As shown in FIG. 1, one exemplary method for manufacturing an image sensor module comprises the steps S1 to S10 as follows.

First of all, the step S1 performs an inspection step. In the step S1, an optical inspection is performed on the glass cover to confirm that there are no defects sufficient to affect the subsequent manufacturing process.

Thereafter, the step S2 is a mounting step where the glass cover is disposed on a substrate. In an exemplary embodiment of the present invention, the mounting step is performed to apply on the substrate a layer of ultraviolet (UV) glue that loses its adhesive properties when exposed to UV light. Subsequently, the glass cover is attached to the substrate through the layer of UV glue.

Next, step S3 is a sawing step where the glass cover is sawed equidistantly, thereby forming a plurality of grooves (or trenches) with a specific depth inside the glass cover. In other exemplary embodiments of the present invention, such grooves with a certain depth inside the glass cover can also be formed utilizing other physical or chemical processes. In doing so, the glass cover is cut (sawed) into multiple glass units. It should be noted that the trenches with a specific depth serve as the interface filling material in subsequent steps. This will be described later and in detail.

Next, the step S4 that is a cleaning step cleans the glass cover (or so-called “various glass units”) on which the grooves have been formed in the step S3 prior to performing subsequent processes.

Subsequently, the step S5, i.e., a filling step is performed to fill the grooves formed in the step S3 with an interfacial material (e.g., a filling material). Alternatively, the interfacial material is a thermosetting or light-curing filling material in other exemplary embodiments of the present invention.

It should be noted that the aforementioned interfacial material is optically transparent and includes, but not limited to, materials that can be water based, solvent based, hot melt based, and free radical curable. In an exemplary embodiment of the present invention, the free radical curing type interfacial material can be selected from active energy ray curing type materials such as electron beam curing type or ultraviolet curing type material. Specifically, active energy ray curing type materials that can be cured in a short time, or ultraviolet-curable materials that can be cured with low energy may be preferable.

Subsequently, the step S6 is a curing (or solidification) step and performs a curing process on the interfacial material that is filled in the grooves in the step S5, thereby forming cured (or solidified) interfacial material (or “solidified interface fillers”). In an exemplary embodiment of the present invention, the curing step may be performed by heat curing, light curing or other curing procedures according to the selected interfacial material.

Thereafter, the step S7 performs another sawing step again, sawing the solidified interface fillers in the grooves of the step 6 to form various independent electronic semi-finished products. It should be particularly noted here that the “electronic semi-finished product” disclosed in embodiments of the present invention refers to a glass unit with a cured interface filler on the edge. The electronic semi-finished product can be used for subsequent complementary metal oxide semiconductor image sensor (CMOS Image Sensor, CIS) packaging. Additionally, each of the electronic semi-finished products forms an image sensor molded ball grid array module during an image sensor molded ball grid array (ImBGA) process, thereby obtaining the image sensor modules of embodiments of the present invention.

Subsequently, the step S8 performs another clean process again, prior to the subsequent processes, cleaning the electronic semi-finished product of the step S7 and the substrate.

Next, the step S9 is a debonding step that is performed to separate the independent electronic semi-finished products cleaned in the step S8 from the substrate. For example, in exemplary embodiments of the present invention, the UV glue coated on the substrate in the step S1 is dissociated after being irradiated with ultraviolet light in the step S9, and eventually loses its adhesive properties.

Subsequently, in the step S10, multiple independent electronic semi-finished products separated from the substrate are obtained due to that the UV glue on the substrate loses viscosity.

Following the step S10, each independent electronic semi-finished product forms an ImBGA module during an image sensor molded ball grid array (ImBGA) process, therefore the image sensor modules of embodiments of the present invention are obtained. It should be noted that, in other exemplary embodiments of the present invention, the image sensor molded ball grid array (ImBGA) process is performed to fix each of the electronic semi-finished products on the chip. Furthermore, in other embodiments of the present invention, after each electronic semi-finished product is attached to the chip, a sealing process is further performed by applying a sealant around a periphery region of each electronic semi-finished product to protect each electronic semi-finished product. Additionally, in other embodiments of the present invention, various solder balls are further formed on an opposite surface of the IC board subsequent to the sealing process, thereby obtaining the ImBGA module. It should also be noted that, in other embodiments of the present invention, the sealing process provides the solidified interface fillers serving as a buffer material between the electronic semi-finished products and the sealant.

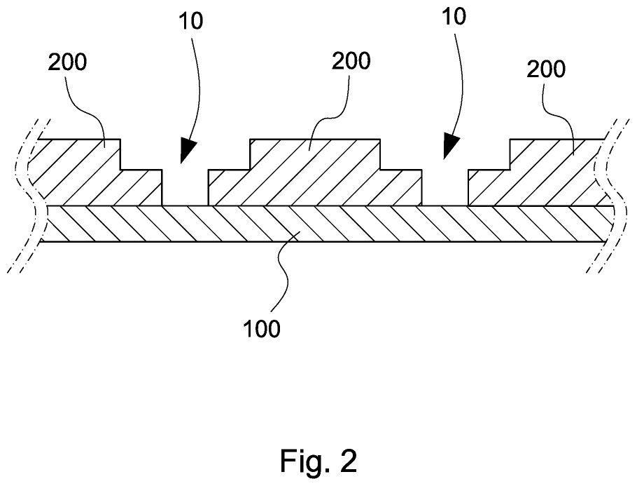

Referring to FIG. 2 to FIG. 5, they illustrate specific steps of the method for manufacturing an image sensor module in accordance with an embodiment of the present disclosure, and relevant concept will be further described as follows.

As shown in FIG. 2, in an embodiment of the present invention, the step S4 is performed, subsequent to the steps S1 to S3 as shown in FIG. 1, to clean various glass units 200 and the grooves 10 between the adjacent glass units 200 on the substrate 100.

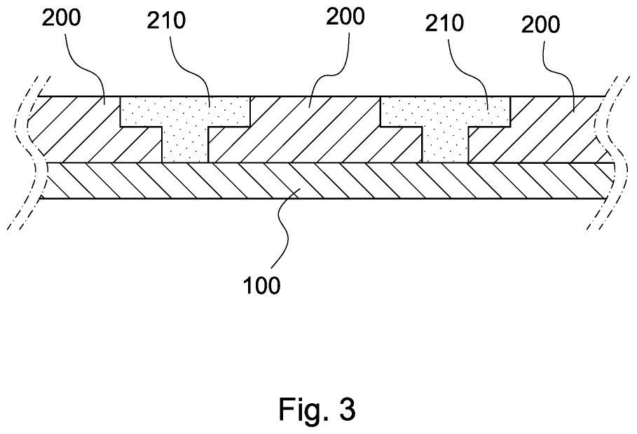

As shown in FIG. 3, in an embodiment of the present invention, the steps S5 to S6 as shown in FIG. 1 are implemented to form solidified interface fillers 210 in the grooves 10 between the glass units 200.

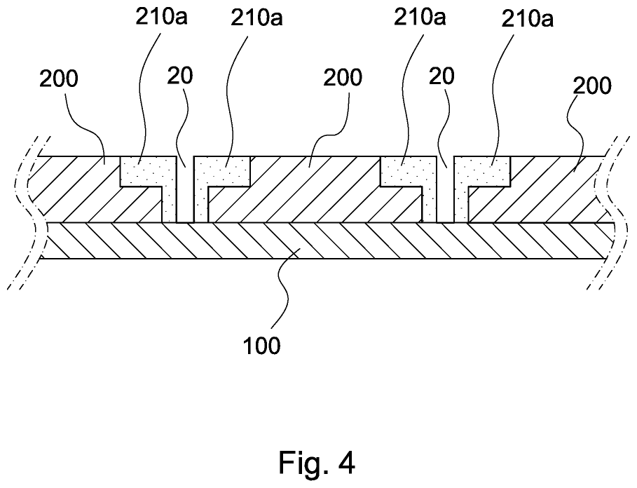

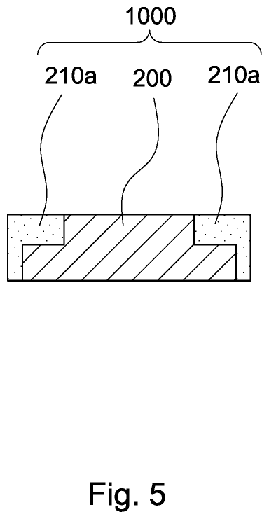

As shown in FIG. 4, in an embodiment of the present invention, the step S7 of FIG. 1 is implemented to saw each interface filler 210 cured in the grooves 10 in the step 6 so that various independent electronic semi-finished products 1000 (see FIG. 5 also) are formed. As mentioned above, every single electronic semi-finished product 1000 in embodiments of the present invention refers to the glass unit 200 with the solidified interface filler 210a on the edge.

As shown in FIG. 5, in an embodiment of the present invention, the steps S8 to S10 of FIG. 1 are executed to obtain electronic semi-finished products 1000 composed of the solidified interface fillers 210a and the glass unit 200.

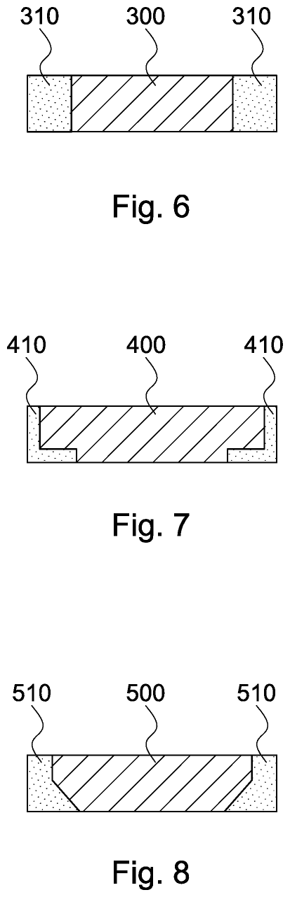

In addition, referring to FIG. 6 to FIG. 8, they illustrate alternative glass covers for the image sensor module in accordance with embodiments of the present disclosure.

In other exemplary embodiments of the present invention, a method for manufacturing an image sensor module is disclosed. The method includes the following steps of: disposing a glass cover on a substrate; sawing the glass cover into a plurality of glass units; performing a first clean process; forming an interfacial material between the adjacent glass units; solidifying the interfacial material to form various solidified interface fillers; sawing along the centerline of each solidified interface fillers; performing a second clean process; performing a debonding process to form a plurality of independent electronic semi-finished products for complementary metal oxide semiconductor image sensor (CMOS Image Sensor, CIS) packaging; and performing an image sensor molded ball grid array (ImBGA) process where each electronic semi-finished product forms an ImBGA module, thereby obtaining the image sensor module.

In other exemplary embodiments of the present invention, each electronic semi-finished product is attached to the chip in the ImBGA process. Thereafter, the chip is arranged on an IC board, and a sealing process is further performed by applying a sealant on a periphery region of each electronic semi-finished product to protect each electronic semi-finished product. Subsequently, various solder balls are further formed on an opposite surface of the IC board subsequent to the sealing process, thereby obtaining the ImBGA module.

As shown form FIG. 6 to FIG. 8, different types of electronic semi-finished products 1000 are thus obtained. For example, the electronic semi-finished product 1000 of FIG. 6 (i.e., composed of the solidified interface fillers 310 and the glass unit 300) is a rectangular glass cover. The electronic semi-finished product 1000 of FIG. 7 (i.e., composed of the solidified interface fillers 410 and the glass unit 400) is a T-shaped glass cover. The electronic semi-finished product 1000 of FIG. 8 (i.e., composed of the solidified interface fillers 510 and the glass unit 500) is a beveled glass cover.

While this invention has been described with respect to at least one embodiment, the invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for manufacturing an image sensor module, including:
disposing a glass cover on a substrate;
sawing the glass cover into a plurality of glass units;
forming a plurality of solidified interface fillers, each being between the adjacent glass units;
sawing along the centerline of each solidified interface filler to form a plurality of independent electronic semi-finished products for complementary metal oxide semiconductor image sensor (CMOS Image Sensor, CIS) packaging; and
performing an image sensor molded ball grid array (ImBGA) process to obtain the image sensor module.

2. The method of claim 1, wherein each electronic semi-finished product forms an ImBGA module in the ImBGA process so that the image sensor module is obtained.

3. The method of claim 2, wherein each electronic semi-finished product is attached to a chip in the ImBGA process

4. The method of claim 3, wherein, after each electronic semi-finished product is attached to the chip, a sealing process is further performed by applying a sealant around a periphery region of each electronic semi-finished product to protect each electronic semi-finished product.

5. The method of claim 4, wherein the chip is located on an IC board, and various solder balls are further formed on an opposite surface of the IC board after the sealing process, thereby obtaining the ImBGA module.

6. The method of claim 4, wherein the solidified interface fillers serve as a buffer material between the electronic semi-finished products and the sealant.

7. The method of claim 1, wherein a first clean process is performed prior to the step of forming the solidified interface fillers between the adjacent glass units.

8. The method of claim 1, wherein a second clean process and a debonding process are further performed after the step of sawing along the centerline of each solidified interface filler.

9. A method for manufacturing an image sensor module, including:
disposing a glass cover on a substrate;
sawing the glass cover into a plurality of glass units;
performing a first clean process;
forming an interfacial material between the adjacent glass units;
solidifying the interfacial material to form various solidified interface fillers;
sawing along the centerline of each solidified interface fillers,
performing a second clean process;
performing a debonding process to form a plurality of independent electronic semi-finished products for complementary metal oxide semiconductor image sensor (CMOS Image Sensor, CIS) packaging; and
performing an image sensor molded ball grid array (ImBGA) process where each electronic semi-finished product forms an ImBGA module, thereby obtaining the image sensor module.

10. The method of claim 9, wherein each electronic semi-finished product is attached to the chip in the ImBGA process; thereafter, the chip is arranged on an IC board, and a sealing process is further performed by applying a sealant on a periphery region of each electronic semi-finished product to protect each electronic semi-finished product; and various solder balls are further formed on an opposite surface of the IC board subsequent to the sealing process, thereby obtaining the ImBGA module.
